(19) United States
(12) Patent Application Publication
(10) Pub. No.: US 2008/0136004 A1
(43) Pub. Date: Jun. 12, 2008

(54) MULTI-CHIP PACKAGE STRUCTURE AND METHOD OF FORMING THE SAME

(75) Inventors: Wen-Kun Yang, Hsin-Chu City (TW); Chun-Hui Yu, Tainan City (TW); Chao-Nan Chou, Taipei City (TW); Chih-Wei Lin, Gueiren Township (TW); Ching-Shun Huang, Chigtong Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/608,404

(22) Filed: Dec. 8, 2006

(51) Int. Cl. H01L 23/488; H01L 21/56

(52) U.S. Cl. 257/686; 438/109; 257/E23.023; 257/E21.502

(57) ABSTRACT

To pick and place standard first chip size package on a base with a second chip for obtaining an appropriate stacking chip size package than the original chip size package. The package structure has a larger chip size package than the size of the traditional stacking package. Moreover, the terminal pins of the flip chip package may be located on peripheral of LGA package or on array of BGA package.

### BACKGROUND OF THE INVENTION

1. Field of the Invention

This invention relates to a package for semiconductors, and more particularly to a multi-chip package and method of the same.

2. Description of the Prior Art

The semiconductor technologies are developing very fast, and especially semiconductor dies have a tendency toward miniaturization. However, the requirements for the functions of the semiconductor dies have an opposite tendency to variety. Namely, the semiconductor dies must have more I/O pads into a smaller area, so the density of the pins is raised quickly. It causes the packaging for the semiconductor dies to become more difficult and decrease the yield.

The main purpose of the package structure is to protect the dies from outside damages. Furthermore, the heat generated by the dies must be diffused efficiently through the package structure to ensure the operation the dies.

The earlier lead frame package technology is already not suitable for the advanced semiconductor dies due to the density of the pins thereof is too high. Hence, a new package technology of BGA (Ball Grid Array) has been developed to satisfy the packaging requirement for the advanced semiconductor dies. The BGA package has an advantage of that the spherical pins has a shorter pitch than that of the lead frame package and the pins is hard to damage and deform. In addition, the shorter signal transmitting distance benefits to raise the operating frequency to conform to the requirement of faster efficiency. For example, the U.S. Pat. No. 5,629,835 discloses a BGA package, by Mahulikar et al; the U.S. Pat. No. 5,239,198 discloses another package that the FR4 substrates having a pattern of conductive traces thereon are mounted on a PCB; the Taiwan patent No.177,766 discloses a fan out type WLP, by the inventor of the present invention.

Most of the package technologies divide dies on a wafer into respective dies and then to package and test the die respectively. Another package technology, called “Wafer Level Package (WLP)”, can package the dies on a wafer before dividing the dies into respective dies. The WLP technology has some advantages, such as a shorter producing cycle time, lower cost, and no need to under-fill or molding. The U.S. Pat. No. 5,323,051, “Semiconductor wafer level package”, is disclosed a WLP technology by Adams et al. The technology is described as follow.

As shown in FIG. 1a, it illustrates a traditional wire bonding stacking package 100a for BGA (Ball Grid Array) type. Chip 102a is placed on a surface of a chip 101a. The chip 102a has pads 103a contacting to pads 110a of a substrate 106a through wire bonding 104a. As the same, chip 101a has pads 109a contacting to pads 110a of the substrate 106a through wire bonding 105a. In other words, the chip 101 a and chip 102a are coupled to the substrate 106a through the wire bonding 105a and wire bonding 104a respectively. An insulation layer 108a, such as molding material, is injected/coated/printed over a surface of the substrate 106a to cover the chip 101a and chip 102a. The plurality of wire bonding 104a and 105a are molded into interior portions of the molding material 108a. A plurality of solder balls 107a forms a plurality of contacts on the substrate 106a which provide electrical coupling to an external device. In such structure, it is made connection between chips and substrate by wire bonding. There are no external pins on the substrate, and array-laying solder balls are used as connecting points with printed circuit board (PCB). BGA substrate material, which contains polymer and conducting material in a laminated form, is key to package performance.

As shown in FIG. 1b, it illustrates a traditional stacking package 100b for BGA (Ball Grid Array) type. A dielectric layer 104b is coated over a surface of the chip 101b to expose die pads 103b of the chip 101b. A redistributed conductive layer 106b is electroplated over the dielectric layer 104b to connect to the die pads 103b. Another dielectric layer 108b is coated on the redistributed conductive layer 106b to protect the chip 101b. A molding material 109b is printed over the dielectric layer 108b. Chip 102b is placed on a surface of the chip 101b. The molding material 109b surrounds the chip 102b. In such structure, the chip 101b is as a substrate of the BGA package. Via 110b is filled conductive material into holes passing through the dielectric layer 104b and redistributed conductive layer 106b over the redistributed conductive layer 106b to connect the redistributed conductive layer 106b. A dielectric layer 113b is coated over a surface of the chip 102b to expose die pads 112b of the chip 102b. A redistributed conductive layer 105b is formed over the dielectric layer 113b to connect to the die pads 112b. Another dielectric layer 111b is coated on the redistributed conductive layer 105b to expose the redistributed conductive layer 105b and protect the chip 102b. A plurality of solder balls 107b forms a plurality of contacts on the chip 101b and chip 102b which provide electrical coupling to an external device. In such structure, the connection between the chips 101b, 102b and PCB is made by via 110b. In other words, the chip 101a and chip 102a are coupled to PCB through via 110b. Moreover, such BGA package is confined to a limited size due to the chip 101b as a substrate and via 110b forming under the chip 101b, and thereby impacting on heat dissipation issue of the package owing to incapable of extension of the package size. There are no additional external pins on the substrate, and array-laying solder balls are used as connecting points with printed circuit board (PCB).

As aforementioned, the size of the package is limited by the chip size, and the I/O pads are contacted through wire bonding in the conventional arts. Therefore, the package size is incapable of extension and a too short pitch among via results in a problem of signal coupling or signal interface, poor heat dissipation performance.

### SUMMARY OF THE INVENTION

Therefore, the present invention has been made in view of the above problems in the prior arts, and it is an objective of the present invention to provide a multi-chips package structure and a method for manufacturing the same.

Another objective of the present invention is to provide a stacking package structure to maintain an appropriate pitch between two via of the package structure.

Still another objective of the present invention is to avoid problems of signal coupling and signal interface.

Still another objective of the present invention is to raise the yield of the package structure.

Another objective of the present invention is to provide package structure with an adjustable size to keep on using of test equipment, package equipment and print circuit board, etc. having for some fixed sizes die or packages.

As aforementioned, the present invention provides a package structure, comprising a substrate. A first chip is mounted over the substrate. A first molding material (core paste) is formed surrounding the first chip. A first redistributed conductive layer is formed over the first molding material to connect to first pad of the first chip. A second chip with redistributed conductive layer and solder bumps/balls structure is provided and mounted on the first chip. A second redistributed conductive layer is formed over the second chip to connect to second pad of the second chip. Solder bumps/balls are connected to the first redistributed conductive layer and the second redistributed conductive layer through the UBM (Under Bump Metallurgy). A second molding material is formed surrounding and covers the second chip, wherein the second molding material includes via structure passing there through, and wherein via structure is connected to the first redistributed conductive layer.

The present invention also provides a package structure comprising a substrate. A first chip is mounted over the substrate. A first molding material is formed surrounding the first chip, wherein the first molding material includes via structure passing there through. A first redistributed conductive layer is formed over the first molding material to connect to via structure and first pad of the first chip. Metal contactors are formed on via structure. A second chip with redistributed conductive layer and solder bumps/balls structure is provided and mounted on the first chip. A second redistributed conductive layer is formed over the second chip to connect to second pad of the second chip. Solder bumps/balls are connected to the first redistributed conductive layer and the second redistributed conductive layer through the UBM (Under Bump Metallurgy). A second molding material is formed surrounding and covers the second chip.

### BRIEF DESCRIPTION OF THE DRAWINGS

FIG. 1a is schematic diagram of a conventional wire bonding stacking package for BGA type in the conventional arts;

FIG. 1b is schematic diagram of a conventional stacking package for BGA type in the conventional arts;

FIG. 2 is a schematic diagram of a wafer level chip size package according to the present invention;

FIG. 3 is a schematic diagram of a fan-out-chip scale package mounted on a panel (substrate) according to the present invention;

FIG. 4 is a schematic diagram of a process of a stacking two chips package according to the present invention;

FIG. 5 is a schematic diagram of a LGA type stacking two chips package according to the present invention;

FIG. 6 is a schematic diagram of a BGA type stacking two chips package according to the present invention;

FIG. 7 is a schematic diagram of a LGA type stacking two chips package according to the present invention;

FIG. 8 is a schematic diagram of a BGA type stacking two chips package according to the present invention;

FIG. 9 is a schematic diagram of a BGA type stacking three chips package according to the present invention; and

FIG. 10 is a schematic diagram of a BGA type stacking three chips package according to the present invention.

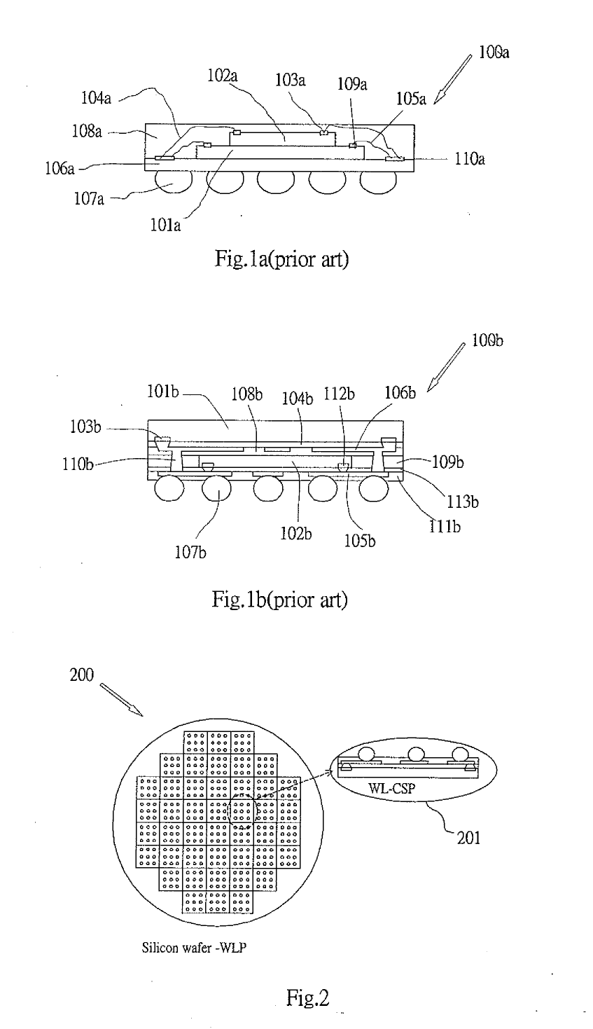

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

Then, the components of the different elements are not shown to scale. Some dimensions of the related components are exaggerated and meaningless portions are not drawn to provide a more clear description and comprehension of the present invention.

The essence of the present invention is to disclose package in package (PIP) structure which is capable of obtaining an appropriate package size by adjusting distance between via through holes. Therefore, the package structure has an adjustable size of package due to die mounted on a substrate. Moreover, the die may be packaged with passive components (ex. capacitors) or other dies with a stacking structure. The detailed structure and process of the present invention will be described below.

The illustration and the corresponding figure below are made through single chip and single redistribution metal layer to simplify and provide a more clear description comprehension of the present invention, but it is not limited.

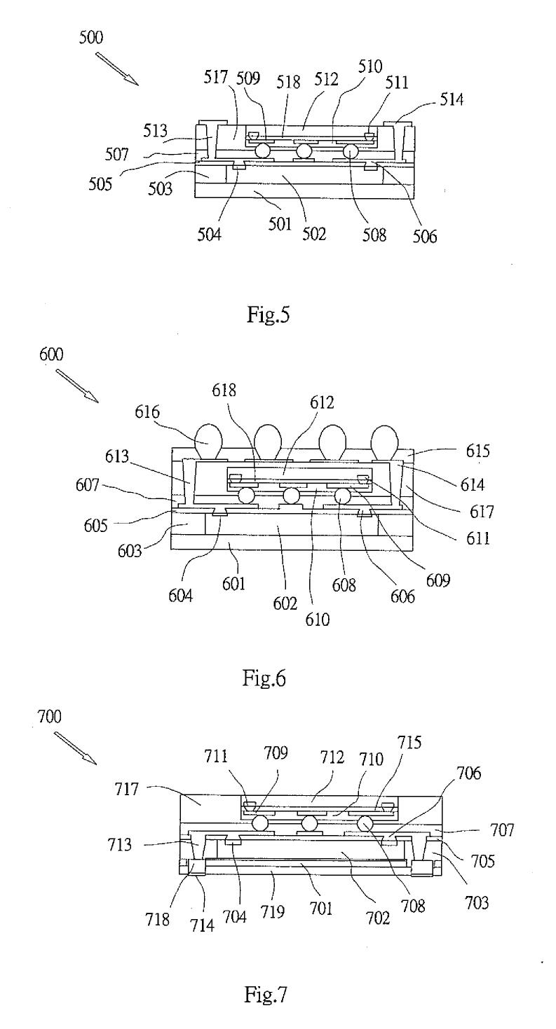

Referring to FIG. 5, it illustrates a stacking LGA type package 500 according to the present invention.

As shown FIG. 5, it shows two chips 502, 512 packages are stacked with each other on a substrate 501. The chip (die) 502 is mounted to the substrate 501. In one embodiment, the substrate comprises metal, Alloy42 (42% Ni-58% Fe), Kovar (29% Ni-17% Co-54% Fe), glass, ceramic, silicon or PCB (for example organic based). The chip 502 package comprises a molding material 503 formed over the substrate 501 surrounding the chip 502. The molding material 503 as a core paste is formed by a printing, coating or injection method. For example, material of the core paste 503 comprises silicone rubber, resin, epoxy compound. A dielectric layer 505 is formed, for example by coating, over a surface of the chip 502 to expose die Al pads 504 of the chip 502. A seed metal layers and redistributed conductive layer 506 is formed, for example by electroplating, over the dielectric layer 505 to connect to the die pads 504. Another dielectric layer 507 is coated on the redistributed conductive layer 506 to expose contact metal pads (UBM) of the redistributed conductive layer 506 and protect the chip 502.

Similarly, the chip 512 package comprises a dielectric layer 518 formed, for example by coating, over a surface of the chip 512 to expose die pads 511 of the chip 512. A seed metal layer and redistributed conductive layer 509 is formed over the dielectric layer 518 to connect to the die pads 511. The redistributed conductive layer 509 is to as a conductive connection of the chip 512 through the UBM and solder bumps/balls. Another dielectric layer 510 is formed over the redistributed conductive layer 509 to expose contact metal pads (UBM) of the redistributed conductive layer 509 and protect the chip 512. As above mentioned, the dielectric layer comprises SINR (Silicone dielectrics—Siloxane Polymer), BCB, PI, silicone based materials. A plurality of solder bumps/balls 508 are connected to the redistributed conductive layer 509 and redistributed conductive layer 506 through UBM, which forms a plurality of electrical contacts on the chip 502 and chip 512.

Molding material 517 is formed over the dielectric layer 507 for surrounding and/or covering the chip 512 and filling the area except the solder bumps/balls 508. The molding material 517 as a core paste is formed by a vacuum printing method. Via 513 is filled conductive material into holes passing through the core paste 517 and the dielectric layer 507 over the redistributed conductive layer 506 to connect the redistributed conductive layer 506. The conductive materials of via 513 can be processed filling at the same time during the electroplating the redistribution metal layers.

In such structure, the chips 502 and 512 may be connected with an external device or PCB by via 513. In other words, the chip 101a and chip 102a are coupled to the external device or PCB through via 513. LGA type package via 513 through holes is located adjacent the chip 512 layer. Via 513 can extend to the area of surface 517 by applying another build up (redistribution metal) layers. Pads 514 are formed to connect through via 513 as contacting points.

Moreover, such package 500 size according to the present invention is larger than two chips 502, 512 packages respectively, which can be determined by the separation of the package, and thereby improving heat dissipation performance of the package owing to capable of extension of the package size, and keep the pitch of connecting pads without any change due to chip size be shrunk.

In another embodiment referring to FIG. 6, it illustrates a stacking BGA type package 600 according to the present invention.

As shown FIG. 6, it shows two chips 602, 612 packages are stacked with each other on a substrate 601. The chip (die) 602 is mounted to the substrate 601. The chip 602 package comprises a molding material 603 formed over the substrate 601 surrounding the chip 602. The molding material 603 as a core paste is formed by a printing method. A dielectric layer 605 is formed over a surface of the chip 602 to expose die pads 604 of the chip 602. A seed metal layers and redistributed conductive layer 606 is formed over the dielectric layer 605 to connect to the die pads 604. Another dielectric layer 607 is formed on the redistributed conductive layer 606 to expose contact pads (UBM) of the redistributed conductive layer 606 and protect the chip 602.

As the same, the chip 612 package comprises a dielectric layer 618 formed over a surface of the chip 612 to expose die pads 611 of the chip 612. A seed metal layers and redistributed conductive layer 609 is formed over the dielectric layer 618 to connect to the die pads 611. The redistributed conductive layer 609 may be as a conductive connection of the chip 612. Another dielectric layer 610 is formed over the redistributed conductive layer 609 to expose contact pads (UBM) of the redistributed conductive layer 609 and protect the chip 612. A plurality of solder bumps/balls 608 are connected to UBM of the redistributed conductive layer 609 and UBM of redistributed conductive layer 606, which forms a plurality of electrical contacts on the chip 602 and chip 612.

Molding material 617 is formed over the dielectric layer 607 and the chip 612 for surrounding the chip 612 and filling the area except the solder balls 608. The molding material 617 as a core paste is formed by a printing method. Via 613 is filled conductive material into holes passing through the core paste 617 and the dielectric layer 607 over the redistributed conductive layer 606 to connect the redistributed conductive layer 606. The conductive material of via 613 can be processed filling at the same time during electro-plating the redistribution metal layers. BOA type package via 613 through holes is in the chip 612 layer. Via 613 can extend to the area except chips 612 located. Another redistributed conductive layer 614 is formed on via 613 as connecting points. Another yet dielectric layer 615 is formed over the redistributed conductive layer 614 and the core paste 617 to expose contact pads of the redistributed conductive layer 614. A plurality of solder bumps/balls 616 are connected to contact pads (UBM) of the redistributed conductive layer 615, which forms a plurality of electrical contacts of the chip 602 and chip 612 with external devices or PCB.

In such structure, the chips 602 and 612 may be connected with an external device or PCB by solder balls 616 through via 613. In other words, the chip 602 and chip 612 are coupled to the external device or PCB through solder balls 616.

In another yet embodiment, referring to FIG. 7, it illustrates another stacking LGA type package 700 according to the present invention.

As shown FIG. 7, it shows two chips 702, 712 packages are stacked with each other on a substrate 701. The chip (die) 702 is mounted to the substrate 701. In one embodiment the substrate 701 comprises metal, Alloy42 (42% Ni-58% Fe), Kovar (29% Ni-17% Co-54% Fe), glass, ceramic, silicon or PCB (for example, organic Print Circuit Board). Moreover, in this preferred embodiment, the substrate 701 is mounted on a rigid substrate 719. The rigid substrate 719 is the non-conductive materials which can be formed by the circuit on it; preferably epoxy type materials laminated or coated. The chip 702 package comprises a molding material 703 formed over the substrate 701 surrounding the chip 702. The molding material 703 as a core paste is formed by a printing method. For example, material of the core paste 703 comprises silicone rubber, resin, epoxy compound. A dielectric layer 705 is formed over a surface of the chip 702 to expose die pads 704 of the chip 702 and via through holes. A seed metal layers and redistributed conductive layer 706 is formed over the dielectric layer 705 to connect to the die pads 704 and filling via 713 by electro-plating process. Another dielectric layer 707 is formed on the redistributed conductive layer 706 to expose the contact pads (UBM) of redistributed conductive layer 706 and protect the chip 702.

Similarly, the chip 712 package comprises a dielectric layer 715 formed over a surface of the chip 712 to expose die pads 711 of the chip 712. A seed metal layers and redistributed conductive layer 709 are formed over the dielectric layer 715 to connect to the die pads 711. The redistributed conductive layer 709 is to as a conductive connection of the chip 712. Another dielectric layer 710 is formed over the redistributed conductive layer 709 to expose contact pads (UBM) of the redistributed conductive layer 709 and protect the chip 712. As above mentioned, the dielectric layer comprises SINR, BCB, PI, silicone dielectrics based materials. A plurality of solder bumps/balls 708 are connected to the redistributed conductive layer 709 and redistributed conductive layer 706, which forms a plurality of electrical contacts on the chip 702 and chip 712.

Molding material 717 is formed over the dielectric layer 707 for surrounding the chip 712 with or without covering the chip 712, and filling the area except the solder bumps/balls 708. The molding material 717 as a core paste is formed by a vacuum printing method. Via 713 is filled conductive material into holes passing through the core paste 717, the dielectric layer 703, the substrate 701 and the rigid substrate 719 over the redistributed conductive layer 706 to connect the redistributed conductive layer 706. A metal contactor 718 is conductive material into holes passing through the substrate 701 and the rigid substrate 719 over Via 713 to connect Via 713 for connecting.

In such structure, the chips 702 and 712 may be connected with an external device or PCB by the metal contactor 718. In other words, the chip 702 and chip 712 are coupled to the external device or PCB through the metal contactor 718. LGA type (peripheral) via through holes 713 located adjacent the chip 702 is in the chip 702 layer and connecting to the rigid substrate 719. The rigid substrate 719 has circuits pattern formed thereon. Via 713 can extend to the area except chips 702, 712 located. Pads 714 are formed on the metal contactor 718 as connecting points.

Moreover, such package 700 size according to the present invention is larger than two chips 702, 712 packages respectively, which can be determined by the separation of the package, and thereby improving heat dissipation performance of the package owing to capable of extension of the package size.

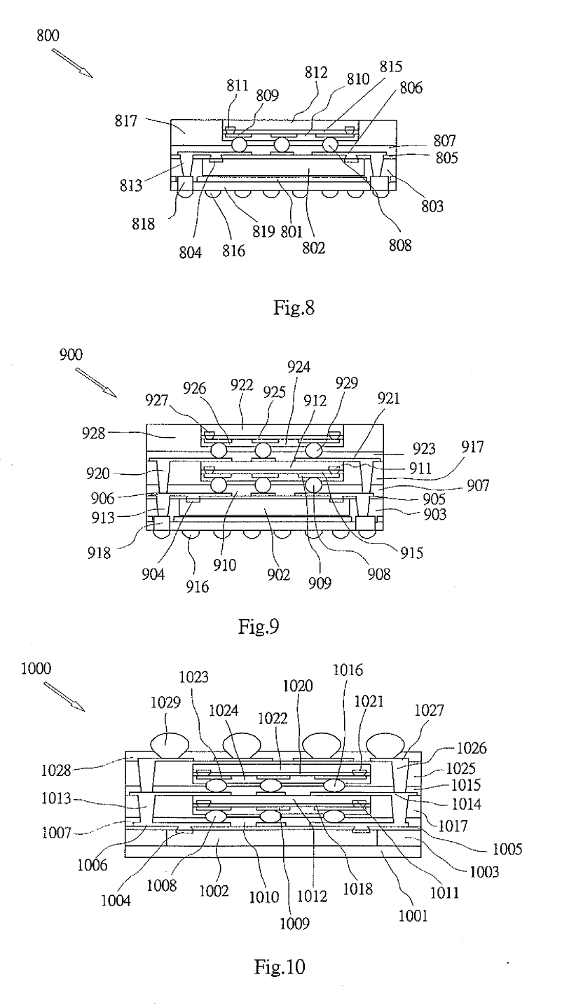

In one embodiment, referring to FIG. 8, it illustrates another stacking BGA type package 800 according to the present invention.

As shown FIG. 8, it shows two chips 802, 812 packages are stacked with each other on a substrate 801. The chip (die) 802 is mounted to the substrate 801. In one embodiment, the substrate 801 comprises metal, Alloy42 (42% Ni-58% Fe), Kovar (29% Ni-17% Co-54% Fe), glass, ceramic, silicon or PCB (for example, organic Print Circuit Board). Moreover, in this preferred embodiment, the substrate 801 is mounted on a rigid substrate 819. The chip 802 package comprises a molding material 803 formed over the substrate 801 surrounding the chip 802. The molding material 803 as a core paste is formed by a printing method. For example, material of the core paste 803 comprises silicone rubber, resin, epoxy compound. A dielectric layer 805 is formed over a surface of the chip 802 to expose die pads 804 of the chip 802 and via holes, and via holes can be processed by lithography process or laser drilling process. A seed metal layers and redistributed conductive layer 806 are formed over the dielectric layer 805 to connect to the die pads 804 and via by electro-plating process. Another dielectric layer 807 is formed on the redistributed conductive layer 806 to expose contact pads (UBM) of the redistributed conductive layer 806 and protect the chip 802.

Similarly, the chip 812 package comprises a dielectric layer 815 formed over a surface of the chip 812 to expose die pads 811 of the chip 812. A seed metal layers and redistributed conductive layer 809 are formed over the dielectric layer 815 to connect to the die pads 811. The redistributed conductive layer 809 is to as a conductive connection of the chip 812. Another dielectric layer 810 is formed over the redistributed conductive layer 809 to expose contact pads (UBM) of the redistributed conductive layer 809 and protect the chip 812. As above mentioned, the dielectric layer comprises SINR, BCB, PI, silicone dielectrics based. A plurality of solder bumps/balls 808 are connected to the redistributed conductive layer 809 and redistributed conductive layer 806, which forms a plurality of electrical contacts on the chip 802 and chip 812.

Molding material 817 is formed over the dielectric layer 807 for surrounding the chip 812 and with or without cover the chip 812, and filling the area except the solder balls 808. The molding material 817 as a core paste is formed by a vacuum printing method. Via 813 is filled conductive material into holes passing through the core paste 817, the dielectric layer 803, the substrate 801 and the rigid substrate 819 over the redistributed conductive layer 806 to connect the redistributed conductive layer 806. A metal contactor 818 is conductive material into holes passing through the substrate 801 and the rigid substrate 819 over Via 813 to connect Via 813 for connecting.

In such structure, the chips 802 and 812 may be connected with an external device or PCB by the metal contactor 818. In other words, the chip 802 and chip 812 are coupled to the external device or PCB through the metal contactor 818. BGA type (array) via through holes 813 located adjacent the chip 802 is in the chip 802 layer and connecting to the rigid substrate 819. The rigid substrate 819 has circuits pattern formed thereon. Via 813 can extend to the area except chips 802, 812 located. Solder balls 816 are formed on the metal contactor 818 as connecting points.

Moreover, such package 800 size according to the present invention is larger than two chips 802, 812 packages respectively, which can be determined by the separation of the package, and thereby improving heat dissipation performance of the package owing to capable of extension of the package size.

In one embodiment, referring to FIG. 9, it illustrates a BGA type package 900 with three stacking packages (CSP) according to the present invention.

As shown FIG. 9, it shows three chips 902, 912, 922 packages are stacked with each other on a substrate 901. The chip (die) 902 is mounted to the substrate 901. In one embodiment, the substrate 901 comprises metal, Alloy42 (42% Ni-58% Fe), Kovar (29% Ni-17% Co-54% Fe), glass, ceramic, silicon or PCB. Moreover, in this preferred embodiment, the substrate 901 is mounted on a rigid substrate 919. The chip 902 package comprises a molding material 903 formed over the substrate 901 surrounding the chip 902. The molding material 903 as a core paste is formed by a vacuum printing method. For example, material of the core paste 903 comprises silicone rubber, resin, epoxy compound. A dielectric layer 905 is formed over a surface of the chip 902 to expose die pads 904 of the chip 902 and via holes by electro-plating process, the via holes open process can be performed by a lithography or laser drilling process. A seed metal layers and redistributed conductive layer 906 are formed over the dielectric layer 905 to connect to the die pads 904 and via 913. Another dielectric layer 907 is formed on the redistributed conductive layer 906 to expose contact pads (UBM) of the redistributed conductive layer 906 and protect the chip 902.

Similarly, the chip 912 package comprises a dielectric layer 915 formed over a surface of the chip 912 to expose die pads 911 of the chip 912. A seed metal layers and redistributed conductive layer 909 are formed over the dielectric layer 915 to connect to the die pads 911, The redistributed conductive layer 909 is to as a conductive connection of the chip 912. Another dielectric layer 910 is formed over the redistributed conductive layer 909 to expose contact pads (UBM) of the redistributed conductive layer 909 and protect the chip 912. As above mentioned, the dielectric layer comprises SINR, BCB, PI, silicone dielectrics based. A plurality of solder bumps/balls 908 are connected to the UBM of redistributed conductive layer 909 and UBM of the redistributed conductive layer 906, which forms a plurality of electrical contacts on the chip 902 and chip 912.

Molding material 917 is formed over the dielectric layer 907 for surrounding the chip 912 and filling the area except the solder balls 908. The molding material 917 as a core paste is formed by a vacuum printing method. Via 913 is filled conductive material into holes passing through the core paste 917, the dielectric layer 903, the substrate 901 and the rigid substrate 919 over the redistributed conductive layer 906 to connect the redistributed conductive layer 906. A metal contactor 918 is conductive material into holes passing through the substrate 901 and the rigid substrate 919 over Via 913 to connect Via 913 for connecting.

In such structure, the chips 902 and 912 may be connected with an external device or PCB by the metal contactor 918. In other words, the chip 902 and chip 912 are coupled to the external device or PCB through the metal contactor 918. BGA type (array) via through holes 913 located adjacent the chip 902 is in the chip 902 layer and connecting to the rigid substrate 919. The rigid substrate 919 has circuits pattern formed thereon. Via 913 can extend to the area except chips 902, 912 located. Solder balls 916 are formed on the metal contactor 918 as connecting points. Ball terminals 916 of the preferred embodiment are located in chip 902 back site.

Moreover, the chip 922 package comprises a dielectric layer 925 formed over a surface of the chip 922 to expose die pads 927 of the chip 922. A seed metal layers and redistributed conductive layer 926 are formed over the dielectric layer 925 to connect to the die pads 927. The redistributed conductive layer 926 is to as a conductive connection of the chip 922. Another dielectric layer 924 is formed over the redistributed conductive layer 926 to expose the redistributed conductive layer 926 and protect the chip 922. As above mentioned, the dielectric layer comprises SINR, BCB, PI, silicone dielectrics based. A plurality of solder balls 929 are connected to the redistributed conductive layer 926 and redistributed conductive layer 921 to contact via 920.

Another molding material 928 is formed over the dielectric layer 923 for surrounding the chip 922 and filling the area except the solder bumps/balls 929. The molding material 928 as a core paste is formed by a vacuum printing method. Via 920 is filled conductive material into holes passing through the core paste 917, the dielectric layer 907 over the redistributed conductive layer 906 to connect the redistributed conductive layer 906. BGA type (array) via through holes 920 located adjacent the chip 912 is in the chip 912 layer and coupling to via 913.

Moreover, such package 900 size according to the present invention is larger than three chips 902, 912, 922 packages respectively, which can be determined by the separation of the package, and thereby improving heat dissipation performance of the package owing to capable of extension of the package size.

In another embodiment, referring to FIG. 10, it illustrates a stacking BGA type package 1000 according to the present invention.

As shown FIG. 10, it shows three chips 1002, 1012, 1022 packages are stacked with each other on a substrate 1001. The chip (die) 1002 is mounted to the substrate 1001. The chip 1002 package comprises a molding material 1003 formed over the substrate 1001 surrounding the chip 1002. The molding material 1003 as a core paste is formed by a vacuum printing method. A dielectric layer 1005 is formed over a surface of the chip 1002 to expose die pads 1004 of the chip 1002. A seed metal layers and redistributed conductive layer 1006 are formed over the dielectric layer 1005 to connect to the die pads 1004. Another dielectric layer 1007 is formed on the redistributed conductive layer 1006 to expose contact pads of the redistributed conductive layer 1006 and protect the chip 1002.

As the same, the chip 1012 package comprises a dielectric layer 1018 formed over a surface of the chip 1012 to expose die pads 1011 of the chip 1012. A seed metal layers and redistributed conductive layer 1009 are formed over the dielectric layer 1018 to connect to the die pads 1011. The redistributed conductive layer 1009 may be as a conductive connection of the chip 1012. Another dielectric layer 1010 is formed over the redistributed conductive layer 1009 to expose the contact pads of redistributed conductive layer 1009 and protect the chip 1012. A plurality of solder bumps/balls 1008 are connected to the redistributed conductive layer 1009 and redistributed conductive layer 1006, which forms a plurality of electrical contacts on the chip 1002 and chip 1012.

Molding material 1017 is formed over the dielectric layer 1007 and the chip 1012 for surrounding the chip 1012 and filling the area except the solder bumps/balls 1008. The molding material 1017 as a core paste is formed by a vacuum printing method. Via through holes can be formed by a lithography or laser drilling process. Via 1013 is filled conductive material into holes passing through the core paste 1017 and the dielectric layer 1007 over the redistributed conductive layer 1006 to connect the redistributed conductive layer 1006. BGA type package via 1013 through holes is in the chip 1012 layer. Via 1013 can extend to the area except chips 1012 located. Another redistributed conductive layer 1014 is formed on via 1013 as connecting points. Another yet dielectric layer 1015 is formed over the redistributed conductive layer 1014 and the core paste 1017 to expose contact pads of the redistributed conductive layer 1014. A plurality of solder bumps/balls 1016 are connected to the redistributed conductive layer 1015, which forms a plurality of electrical contacts of the chip 1002 and chip 1012.

Similarly, the chip 1022 package comprises a dielectric layer 1020 formed over a surface of the chip 1022 to expose die pads 1021 of the chip 1022. A seed metal layers and redistributed conductive layer 1023 are formed over the dielectric layer 1020 to connect to the die pads 1021. The redistributed conductive layer 1023 may be as a conductive connection of the chip 1022. Another dielectric layer 1024 is formed over the redistributed conductive layer 1023 to expose contact pads of the redistributed conductive layer 1023 and protect the chip 1022. A plurality of solder bumps/balls 1016 are connected to the redistributed conductive layer 1023 and redistributed conductive layer 1014, which forms a plurality of electrical contacts on the chip 1022 and chip 1012.

Molding material 1025 is formed over the dielectric layer 1015 and the chip 1022 for surrounding and covering the chip 1022 and filling the area except the solder bumps/balls 1016. The molding material 1025 as a core paste is formed by a vacuum printing method. Via 1026 is filled conductive material into holes passing through the core paste 1025 and the dielectric layer 1015 over the redistributed conductive layer 1014 to connect the redistributed conductive layer 1014. BGA type package via 1026 through holes is in the chip 1022 layer. Via 1026 can extend to the area except chips 1022 located. Another redistributed conductive layer 1027 is formed on via 1027 as connecting points. Another yet dielectric layer 1028 is formed over the redistributed conductive layer 1027 and the core paste 1025 to expose the redistributed conductive layer 1027. A plurality of solder bumps/balls 1029 are connected to contact pads (UBM) of the redistributed conductive layer 1027, which forms a plurality of electrical contacts of the chip 1002, chip 1012 and chip 1022. Ball terminals 1029 of the preferred embodiment are located in the chip 1022 back side.

In such structure, the chips 1002, 1012 and 1022 may be connected with an external device or PCB by solder balls 1022 through via 1023, 1013. In other words, the chips 1002, 1012 and 1022 are coupled to the external device or PCB through solder balls 1029.

As above-mentioned, the detailed process of the stacking BGA/LGA type package according to the present invention will be described below.

Referring to FIG. 2, it illustrates a processed silicon wafer level package 200 according to the present invention. The processed silicon wafer level package 200 is provided with a plurality of chip size packages (CSP) 201 which has balls or bumps as terminal contactors. The chip of FIG. 2 is packaged as wafer level chip scale package with solder balls/bump structure, using redistributed conductive layer in build up layers. The first dielectric layer is coated and then open the first contact pads (Al bonding pads). Seed metal layers are sputtered after the Al pads cleaned. The materials of sputtering metal are preferably Ti/Cu or Ti/W/Cu. Photo resist is coated and using the photo resist as a mask to form the redistribution metal layer (RDL) layer, then, the electroplating process is to form the redistributed metal layer, preferably metal as Cu/Au and/or Cu/Ni/Au materials. The top layer dielectric layer is coated to cover the surface and expose the contact pads area to form the UBM for solder bumps/balls connecting. The chip size package (CSP) 201 is a basic structure of the above mentioned stacking BGA/LGA package, for instant the chips 512, 612, 712, 812, 912, 922, 1012 and 1022 processed as FIG. 2.

The thickness of the processed silicon wafer may be decreased by back lapping to get a thickness range of 50-300 μm. The processed silicon wafer with the aforementioned thickness is easily sawed to divide the dies on the wafer into respective dies. A dielectric layer (protection layer) is formed on the processed silicon wafer before sawing to protect dies form damages.

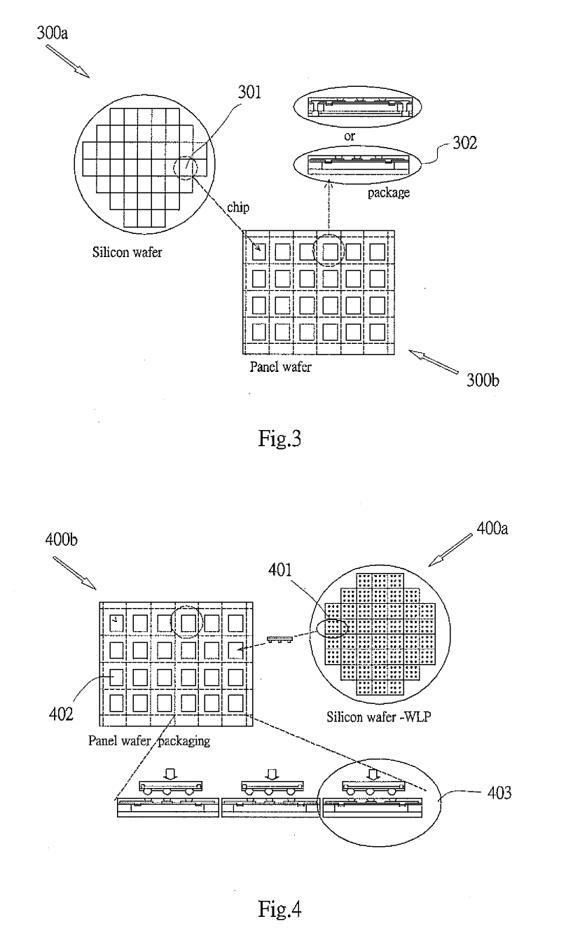

Referring to FIG. 3, it illustrates a processed panel wafer level package according to the present invention. The processed silicon wafer 300a is provided with a plurality of chips 301 are mounted on a substrate/panel. The chips of FIG. 3 are placed on the panel and filling paste to make panel form and using the build up layers process to make contactors. Once the panel wafer is formed, the first dielectric layer is coated on the surface of the chips 301 and exposing the first open area (Al bonding pads or via pads if the wafer has been processed the RIDL inside). A seed metal layers are sputtered on the panel wafer after the first open area cleaned; the preferably seed metal layers are Ti/Cu or Ti/W/Cu materials. Photo resist is coated on the seed metal layer and to form the RDL pattern, then, applying the electro-plating process to form the redistributed conductive layers on the seed metal layers; preferably the metals are Cu/Au or Cu/Ni/Au. The following step is to strip the photo-resist and wet etching the seed metal layers to form the redistribution metal layers. Top dielectric layer is coated on the redistribution metal layers and exposing the contact pads area to form the UBM (Under Balls Metal). The chip size package (CSP) 302 is another basic structure of the above mentioned stacking BGA/LGA package, for instant the chips 502, 602, 702, 802, 902, 1002.

The chips 301 are tested to choose standard good chips, and then the standard good chips 301 are cut to mount onto a new base (panel) 30b. For example, the chips 301 are employed by a pick and place fine alignment system to mount on the panel wafer 300b, it preferably accuracy less than 10 um for each chips be mounted on the panel. In the package 302, Al pads of the chip 301 are connected to metal contactors (redistributed metal trace) by a fan-out wafer level package process (build up layers process).

Referring to FIG. 4, it illustrates a stacking process of two chip size packages according to the present invention.

The chip size packages (CSP) 401 of the silicon wafer level package 400a which has balls or bumps as terminal contactors are tested to choose standard good chips, and then the standard good chip size packages 401 are employed by a dicing saw process and placing on the top of a panel 400b with face down (balls face down) by a flip chip bonder to mount on the base (panel) 400b by an heat re-flow process to anneal the soldering metal to form the electrical conductivity, and thereby forming a stacking package 403.

Reflowing the panel with chip 402 (with the built up layers and contact pads already) is to solder join the chip 401 on the panel, and using the build up layer process to make the final contactors either on the circuit site or the back site. Final terminal pins are located on peripheral of LGA package or on array of BGA package.

Final, the stacking packaged base with the aforementioned structure is sawed along the sawing line to isolate respective stacking package.

The package process of the present invention even can apply to form multi chip with stacking structure. In other words, although FIG. 10 only shows a stacking package structure with three chips, it is obvious that a stacking package structure with more than three chips can be obtained as aforementioned. In other words, the package of the present invention may comprise more components (active devices and passive devices) stacking by using build up layer and via holes process.

Hence, according to the present invention, the aforementioned package structure can maintain an appropriate pitch between two adjacent balls of the package structure. Therefore, the present invention can avoid the problems of signal coupling and signal interface. Moreover, the package structure can adjust size of the stacking package due to chip mounted on a substrate, and therefore the present invention can raise the yield of the package structure. Moreover, the package size of the present invention can be easily adjusted to test equipment, package equipment, and fit to the print circuit board, etc.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. Thus, while the preferred embodiment of the invention has been illustrated and described, it will be appreciated that various changes can be made therein without departing from the spirit and scope of the invention.

Having described the invention, the following is claimed:

1. A semiconductor device package structure, comprising:
a substrate;
a first chip mounted over said substrate;
a first molding material formed surrounding said first chip;
a first redistributed conductive layer formed over said first molding material and first dielectric layer to connect to and first pad of said first chip;
a second chip;
a second redistributed conductive layer formed over said second chip to connect to second pad of said second chip;
solder bumps/balls connected to said first redistributed conductive layer and said second redistributed conductive layer; and
a second molding material formed surrounding said second chip, wherein said second molding material includes via structure passing there through, wherein said via structure is connected to said first redistributed conductive layer.

2. The package in claim 1, wherein the material of said substrate includes metal, Alloy42 (42% Ni-58% Fe), Kovar (29% Ni-17% Co-54% Fe), glass, ceramic, silicon or PCB (Print Circuit Board).

3. The package in claim 1, wherein the material of said first and second molding layer includes silicone rubber, resin or epoxy compound.

4. The package in claim 1, wherein material of said first and second redistributed conductive layer includes Cu/Au, Cu/Ni/Au alloy.

5. The package in claim 1, wherein the material of said via structure includes Ti/Cu, Cu/Au, Cu/Ni/Au alloy.

6. The package in claim 1, further comprising a third redistributed conductive layer formed over said second molding material connected to said via structure.

7. The package in claim 6, further comprising BGA (Ball Grid Array) package solder balls formed on said third redistributed conductive layer.

8. The package in claim 1, further comprising metal pads as LGA (Lane Grid Array) package pads formed on said via structure and peripheral of said LGA package.

9. The package in claim 1, further comprising more components stacking by using build up layers and corresponding vias.

10. A semiconductor device package structure, comprising:
a substrate;
a first chip mounted over said substrate;
a first molding material formed surrounding said first chip, wherein said first molding material includes via structure passing there through;
a first redistributed conductive layer formed over said first molding material to connect to said via structure and first pad of said first chip;
metal contactors formed on said via structure;
a second chip;
a second redistributed conductive layer formed over said second chip to connect to second pad of said second chip;
solder balls connected to said first redistributed conductive layer and said second redistributed conductive layer; and
a second molding material formed surrounding said second chip.

11. The package in claim 10, wherein the material of said substrate includes metal, Alloy42 (42% Ni-58% Fe), Kovar (29% Ni-17% Co-54% Fe), glass, ceramic, silicon or PCB (organic print circuit board).

12. The package in claim 10, wherein the material of said first and second molding layer includes silicone rubber, resin or epoxy compound.

13. The package in claim 10, wherein material of said first and second redistributed conductive layer includes Cu/Au, Cu/Ni/Au alloy.

14. The package in claim 10, wherein the material of said via structure includes Ti/Cu, Cu/Au or Cu/Ni/Au alloy.

15. The package in claim 10, further comprising a rigid substrate connected to said substrate.

16. The package in claim 15, wherein said rigid substrate comprises non-conductive materials.

17. The package in claim 15, wherein said rigid substrate has circuit pattern formed thereon.

18. The package in claim 10, further comprising BGA (Ball Grid Array) package solder balls formed on said metal contactors and said rigid substrate.

19. The package in claim 10, further comprising metal pads as LGA (Lane Grid Array) package pads formed on said via structure and peripheral of said LGA package.

20. The package in claim 10, further comprising more components stacking by using build up layers and corresponding vias.

21. A method of making package structure, comprising;
providing first wafer level chip scale package with solder balls/bump connected first redistributed conductive layer in build up layers;
providing a processed silicon wafer with a plurality of second chips;
dicing said processed silicon wafer to form a plurality of individual second chips;
placing said plurality of second chips on a panel;
forming a molding material on said panel surrounding said second chips;
forming a first dielectric layer on the surface of said second chips and exposing a first open area;
forming a seed metal layers on said first dielectric layer;
forming a second redistributed conductive layers on said seed metal layers;
forming a second dielectric layer on said second redistributed conductive layers to expose contact pads area;
dicing said first wafer level chip scale package to form a plurality of individual first chip scale packages; and
placing said first chip scale packages on said panel.
forming a molding material on said panel surrounding said first chip scale package.

22. The method in claim 21, further comprising a step of open via contact holes process passing there through the molding materials to form the final contact terminals.

23. The method in claim 21, further comprising a step of heat re-flowing process to anneal said solder balls/bump.

24. The method in claim 21, wherein said package structure comprises LGA package or BGA package.

25. The method in claim 21, wherein the material of said panel includes metal, Alloy42 (42% Ni-58% Fe), Kovar (29% Ni-17% Co-54% Fe), glass, ceramic, silicon or PCB (organic Print Circuit Board).

26. The method in claim 21, wherein the material of said molding layer includes silicone rubber, resin or epoxy compound.

27. The method in claim 21, wherein material of said first and second redistributed conductive layer includes Cu/Au, Cu/Ni/Au alloy.

28. The method in claim 21, further comprising more components stacking by using build up layers and via holes process.
